(19) United States
(12) Patent Application Publication
(10) Pub. No.: US 2005/0269630 A1
(43) Pub. Date: Dec. 8, 2005

(54) Trench type semiconductor device with reduced Qgd

(76) Inventor: Jianjun Cao, Torrance, CA (US)

Correspondence Address: OSTROLENK FABER GERB & SOFFEN, 1180 AVENUE OF THE AMERICAS, NEW YORK, NY, 100368403, US

(21) Appl. No.: 11/142,034

(22) Filed: Jun. 1, 2005

Related U.S. Application Data
(60) Provisional application No. 60/577,015, filed on Jun. 4, 2004.

(51) Int. Cl. H01L 29/74; H01L 21/336

(52) U.S. Cl. 257/330; 257/328; 438/259

(57) ABSTRACT

A trench type power semiconductor device which includes a buried electrode that is electrically connected to an electrode that can be biased to reach a voltage other than any of the other power electrodes.

### RELATED APPLICATION

This application is based on and claims the benefit of U.S. Provisional Application No. 60/577,015, filed on Jun. 4, 2004, entitled Trench Type MOSFET with Reduced Qgd, to which a claim of priority is hereby made and the disclosure of which is incorporated by reference.

### BACKGROUND OF THE INVENTION

The present invention relates to semiconductor devices and more particularly to trench type MOSgated power semiconductor devices.

Referring to FIG. 1, a trench type power MOSFET according to the prior art includes drift region 10 of one conductivity (e.g. N-type) formed on a substrate 12 of the one conductivity but usually of lower resistivity (higher dopant concentration), base region 14 of another conductivity opposite to the one conductivity (e.g. P-type) over and adjacent drift region 10, trenches 16 extending through base region 14 and terminating at a depth below base region 14, source regions 18 formed in base region 14 each adjacent a respective trench 16, buried source electrodes 20 each residing within and at the bottom of a respective trench 16, and gate electrodes 22 residing within a respective trench above a respective buried source electrode 20. Each buried source electrode 20 is insulated from drift region 10 by an insulation body 24, and from a respective gate electrode by an insulation barrier 26. Also, each gate electrode 22 is insulated from base region 14 by gate insulation bodies 26 each interposed between base region 14 and a respective gate electrode 22. A device according to the prior art further includes source contact 30 which is insulated from each gate electrode 22 by a respective insulation cap 25, and electrically connected to source regions 18, buried source electrodes 20, and high conductivity regions 32 of the another conductivity formed in base region 14, and drain contact 34 which is electrically connected to substrate 12. Because source contact 30 and buried source electrodes 20 are electrically connected, buried source electrodes 20 are biased to the same potential (i.e. the source potential). As a result, the breakdown voltage of the device is improved.

Referring next to FIG. 2, in which like numerals identify like features, another known semiconductor device includes buried electrode 36 disposed within and at the bottom of a respective trench 16. In the device shown by FIG. 2, buried electrode 36 is not electrically connected to source contact 30. Rather, buried electrode 36 is electrically connected to the VRM voltage, which is usually higher than the source voltage (or is positive with respect to). Buried electrode 36 is provided to reduce or eliminate Qgd (gate to drain capacitance) in order to improve the switching characteristics of the device.

It should be noted that gate electrode 22 in the device shown by FIG. 2 includes a horizontal component which extends horizontally over base region 14, and a vertical component which extends vertically into trench 16, but does not span the entire thickness of base region 14. Thus, to operate the device, gate electrode 22 alone cannot be used to form a channel in base region 14 to extend between source regions 18 and drift region 10. That is, a portion of the channel must be formed by the buried electrode 36. Therefore, insulation body 24 interposed between buried electrode 36 and base region 14 must be thin enough (i.e. as thin as gate insulations 28) to allow buried electrode 36 to cause the formation of at least a portion of the channel between source regions 18 and drift region 10. Moreover, because buried electrode 36 is partly responsible for channel formation the resistivity of the channel depends not only on the voltage applied to gate electrodes 22, but the voltage applied to buried electrodes 36. That is, the control of the resistivity of the channel does not solely depend on the voltage applied to gate electrodes 22.

### SUMMARY OF THE INVENTION

It is an object of the present invention to provide a power semiconductor device which exhibits low Qgd and improved BVdss.

A semiconductor device according to the preferred embodiment of the present invention is a trench type power device which includes: a substrate having a first major surface and an opposing second major surface, a drift region of one conductivity formed on the first major surface of the substrate, a base region of another conductivity adjacent the drift region, at least one trench extending through the base region and terminating at a depth below the base region, a buried electrode disposed within the trench below the base region, an insulation body interposed between the buried electrode and the trench walls, an insulated gate electrode disposed in the trench and over the buried electrode in the trench and spanning the entire thickness of the base region, at least one conductive region of the one conductivity formed in the body region, a first power electrode electrically connected to the at least one conductive region, a second power electrode electrically connected to the second major surface of the substrate, a control electrode electrically connected to the gate electrode, and a buried electrode contact electrically connected to the buried electrode.

According to one aspect of the present invention, because the insulated gate spans the thickness of the base region, the formation of the channel and its resistivity are controlled by the gate electrode only.

According to another aspect of the present invention a device according to the present invention can be operated by applying a first voltage to the first power electrode, and applying a second voltage to the buried electrode, whereby the buried electrode is operated at a voltage different from the first voltage. Preferably, the buried electrode is operated at a voltage that is positive with respect to the first power electrode of the device.

Other features and advantages of the present invention will become apparent from the following description of the invention which refers to the accompanying drawings.

### BRIEF DESCRIPTION OF THE DRAWINGS

FIG. 1 shows a cross-sectional view of a power MOSFET according to the prior art.

FIG. 2 shows a cross-sectional view of a power MOSFET according to another prior art concept.

FIG. 3 is a cross-sectional view of a semiconductor device according to the present invention.

FIG. 4 is a top plan view of a semiconductor device according to the present invention.

### DETAILED DESCRIPTION OF THE FIGURES

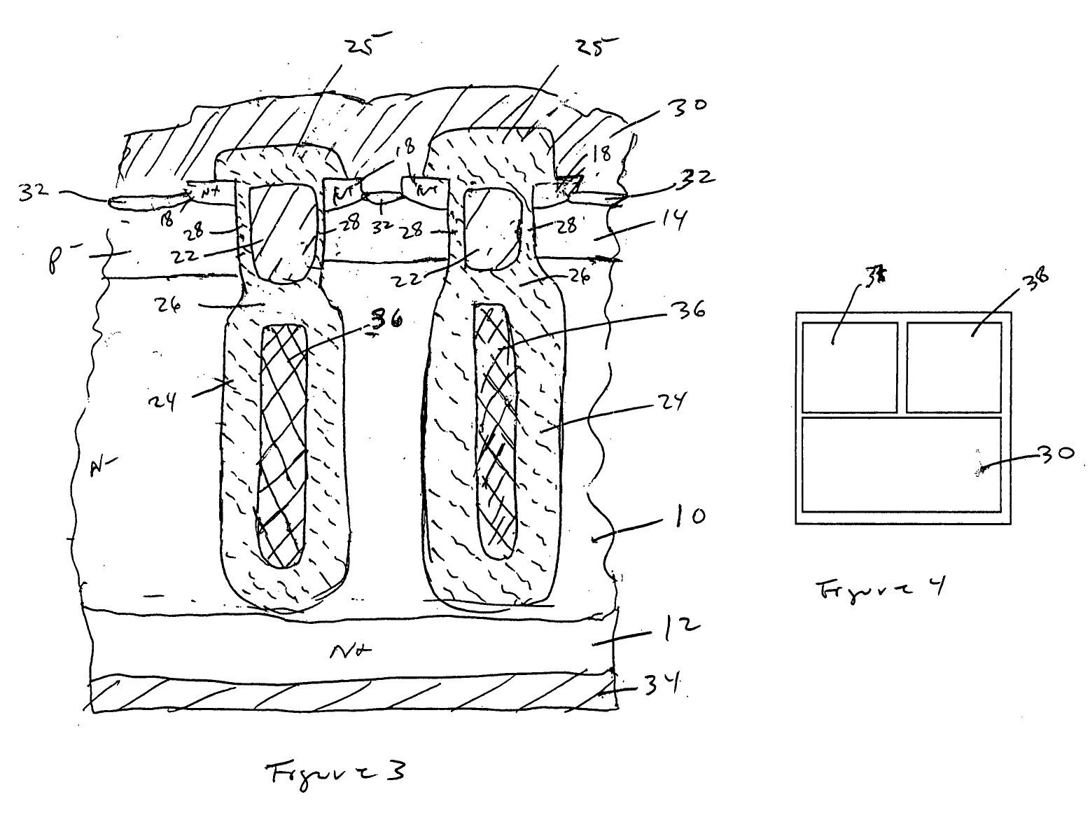

Referring to FIG. 3, a power semiconductor device according to the preferred embodiment of the present invention is a trench type power MOSFET which includes drift region 10 of one conductivity (e.g. N-type) formed on a substrate 12 of the one conductivity but usually of lower resistivity (higher dopant concentration), base region 14 of another conductivity opposite to the one conductivity (e.g. P-type) over and adjacent drift region 10, trenches 16 extending through base region 14 and terminating at a depth below base region 14, first conductive regions of the one conductivity i.e. source regions 18 formed in base region 14 each adjacent a respective trench 16, buried electrodes 36 each residing within and at the bottom of a respective trench 16, and gate electrodes 22 each residing within a respective trench above a respective buried electrode 36.

According to one aspect of the present invention, each buried electrode 36 is electrically connected to a buried electrode contact 38 (see FIG. 4) and insulated from drift region 10 by an insulation body 24, and from a respective gate electrode 22 by an insulation barrier 26. Also, each gate electrode 22 is insulated from base region 14 by gate insulation bodies 26 each interposed between base region 14 and a respective gate electrode 22. A device according to the preferred embodiment of the present invention further includes source contact 30, which is insulated from each gate electrode 22 by a respective insulation cap 25, and electrically connected to source regions 18, and high conductivity regions 32 of the another conductivity formed in base region 14, and drain contact 34 which is electrically connected to substrate 12.

According to one aspect of the present invention gate electrodes 22 span the entire thickness of base region 14. Thus, the resistivity of the channel formed in base region 14 depends solely on the voltage that is applied to gate electrodes 22.

Furthermore, buried electrodes 36 can be insulated from drift region 10 with an insulation body 24 of any desired thickness. In the preferred embodiment of the present invention insulation bodies 28 are preferably thicker than gate insulations 28.

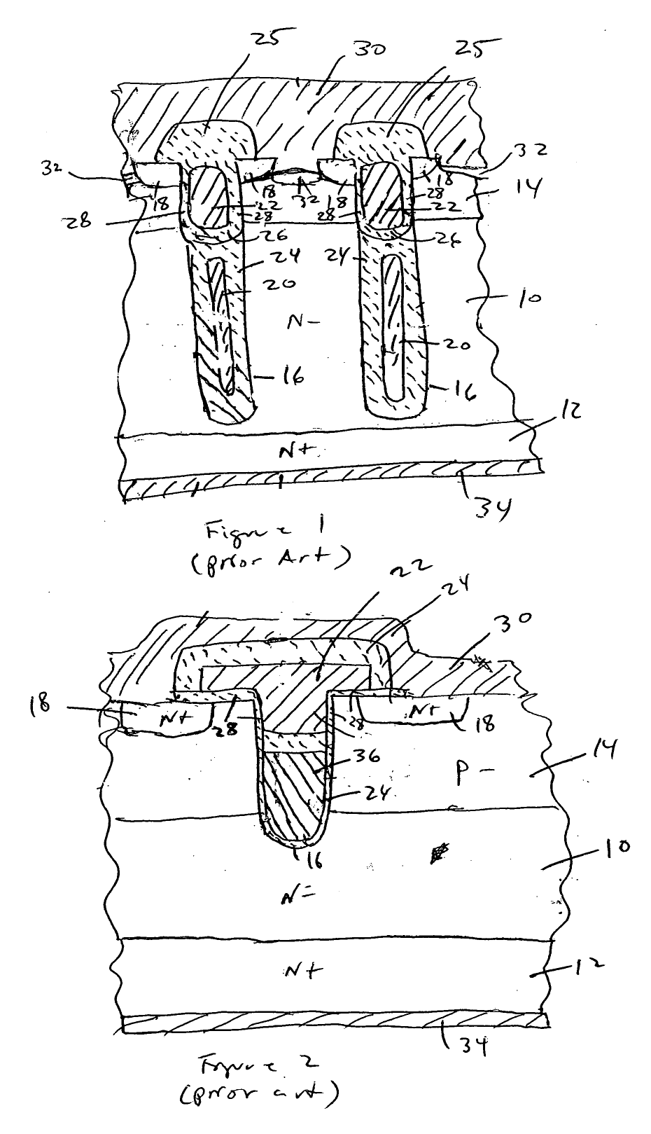

Referring now to FIG. 4, a device according to the present invention includes gate contact 37, which is electrically connected to gate electrodes 22 and buried contact 38 which is electrically connected to buried electrodes 36. Preferably, buried electrodes 36 are biased to be positive with respect to source contact 30 when a device according to the present invention is operated. As a result, the Qgd of the device and thus its switching characteristics are improved. In addition, the breakdown voltage (BVdss) is higher than the prior art shown in FIG. 1, where the buried electrode is connected to the source.

A power semiconductor device according to the preferred embodiment is an N-channel device. Thus, in the preferred embodiment base region 14 is P-type, while source regions 18, drift region 10, and substrate 12 are N-type. Furthermore, buried electrodes 36 and gate electrodes 22 are formed from conductive polysilicon, and insulation bodies 24, gate insulations 28, insulation caps 25, and insulation barrier 26 are formed from an oxide and most preferably silicon dioxide. Source contact 30, drain contact 34, gate contact 37 and buried contact 38 can be formed from any suitable metal such as Al or Alsi.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

1. A power semiconductor device comprising:
a substrate having a first major surface and an opposing second major surface;
a drift region of one conductivity formed on said first major surface of said substrate;
a base region of another conductivity adjacent said drift region;
at least one trench extending through said base region and terminating at a depth below said base region;
a buried electrode disposed within said trench below said base region;
an insulation body interposed between said buried electrode and said trench walls;
an insulated gate electrode disposed in said trench and over said buried electrode in said trench and spanning the entire thickness of said base region;
at least one conductive region of said one conductivity formed in said body region;
a first power electrode electrically connected to said at least one conductive region;
a second power electrode electrically connected to said second major surface of said substrate;
a control electrode electrically connected to said gate electrode; and
a buried contact electrically connected to said buried electrode.

2. A device according to claim 1, wherein said first power electrode is a source electrode; said second power electrode is a drain electrode, and said control electrode is a gate electrode.

3. A device according to claim 1, wherein said buried electrode is comprised of polysilicon.

4. A device according to claim 1, wherein said insulation body is comprised of an oxide.

5. A device according to claim 1, wherein said insulation body is comprised of silicon dioxide.

6. A device according to claim 1, wherein said insulated gate electrode includes gate insulation adjacent said base region and wherein said insulation body is thicker than said gate insulation.

7. A method of operating a power semiconductor device that includes: a substrate having a first major surface and an opposing second major surface; a drift region of one conductivity formed on said first major surface of said substrate; a base region of another conductivity adjacent said drift region; at least one trench extending through said base region and terminating at a depth below said base region; a buried electrode disposed within said trench below said base region; an insulation body interposed between said buried electrode and said trench walls; an insulated gate electrode disposed in said trench and over said buried electrode in said trench and spanning the entire thickness of said base region; at least one conductive region of said one conductivity formed in said body region; a first power electrode electrically connected to said at least one conductive region; a second power electrode electrically connected to said second major surface of said substrate; a control electrode electrically connected to said gate electrode; and a buried electrode contact electrically connected to said buried electrode, comprising:
applying a first voltage to said first power electrode; and
applying a second voltage to said buried electrode, whereby said buried electrode is operated at a voltage different from said first voltage.

8. A device according to claim 7, wherein said second voltage is positive with respect to said first voltage.

9. A power semiconductor device comprising:
a silicon substrate of one conductivity having a first major surface and an opposing second major surface;
a drift region of said one conductivity formed on said first major surface of said substrate;
a base region of another conductivity adjacent said drift region;
at least one trench extending through said base region and terminating at a depth below said base region;
a buried electrode disposed within said trench below said base region;
an insulation body interposed between said buried electrode and said trench walls;
an insulated gate electrode disposed in said trench and over said buried electrode in said trench and spanning the entire thickness of said base region;
at least one source region of said one conductivity formed in said body region;
a source electrode electrically connected to said at least one source region;
a drain electrode electrically connected to said second major surface of said substrate;
a gate contact electrically connected to said gate electrode; and
a buried electrode contact electrically connected to said buried electrode.

10. A device according to claim 9, wherein said buried electrode is comprised of polysilicon.

11. A device according to claim 9, wherein said insulation body is comprised of an oxide.

12. A device according to claim 9, wherein said insulation body is comprised of silicon dioxide.

13. A device according to claim 9, wherein said insulated gate electrode includes gate insulation adjacent said base region and wherein said insulation body is thicker than said gate insulation.
